(19) United States
(12) Patent Application Publication
(10) Pub. No.: US 2022/0374204 A1
(43) Pub. Date: Nov. 24, 2022

(54) HALF-ADDER, FULL-ADDER AND MULTIPLIER BASED ON MEMRISTOR ARRAY

(71) Applicant: ZHUHAI FUDAN INNOVATION INSTITUTE, Zhuhai (CN)

(72) Inventor: Liang Zou, Zhuhai (CN)

(73) Assignee: ZHUHAI FUDAN INNOVATION INSTITUTE, Zhuhai (CN)

(21) Appl. No.: 17/771,826

(22) PCT Filed: Dec. 9, 2019
(86) PCT No.: PCT/CN2019/123887

§ 371 Date: Apr. 26, 2022

(30) Foreign Application Priority Data
Nov. 29, 2019 (CN) 201911206361.0

(51) Int. Cl. G06F 7/544; G06F 7/502

(52) U.S. Cl. CPC G06F 7/5443; G06F 7/502; G11C 13/0002

(57) ABSTRACT

The present invention discloses a memristor array, comprising metal wires and memristors; the metal wires are arranged laterally and vertically; a memristor is arranged at the intersection of every two metal wires; the connection/disconnection of the metal wires is judged according to the resistance values of the memristors; and an adder is constituted according to the resistance value states of the memristors. The present invention provides a memristor-CMOS hybrid multiplication core circuit, in which one input of multiplication can be stored in a memristor network, one part of operation is completed in a memory network, the other part of operation is completed through a CMOS circuit, thereby reducing frequent data calls by half, and the power consumption of the CMOS circuit is further reduced by reducing competitive adventure in the operation process, thereby greatly reducing the overall energy consumption.

### TECHNICAL FIELD

The present invention relates to the technical field of memristors, and more particularly relates to a half-adder, full-adder and multiplier based on a memristor array.

### BACKGROUND

The human society is at a turning point from information society to intelligent society, and artificial intelligence will fundamentally change our way of life. In recent years, with the successful application of big data and deep learning, the computational intelligence degree of the fields such as voice recognition, face recognition, knowledge search and intelligent driving is rapidly increased, and the related research and application receive unprecedented attention. One of the driving forces is ever-increasing computing power. In the past 40 years, with the progress of integrated circuit technology and design, the processing capacity of processors is increased by nearly one hundred billion times. However, the promotion of the computing power is accompanied by a sharp increase in energy consumption. Low power consumption is always the core problem in processor design. Although the energy consumption of single operation decreases with the progress of technology and design, the rate of decrease is far from keeping up with the rate of growth in demand for computing power. In 2016, the electricity consumption of data centers in China has accounted for more than 1.8% of the total, electricity consumption of the whole country, with an annual growth rate of more than 15%. With the rapid growth of the total amount of data in the whole society, the energy consumption of computation has become a key bottleneck in the intelligent society, and it is extremely urgent to solve the problem of energy consumption of data computation.

The traditional digital computers are based on the Von-Neumann architecture, and the data thereof is stored in a dedicated memory unit and called in sequence during computation. Frequent data calls and storages consume a large amount of power. In contrast, biological synapses are highly efficient because of having the functions of storage and computation. Therefore, according to the characteristic of fusion of storage and computation of biological neural computation, aiming at the deep learning convolutional neural network widely used in the field of artificial intelligence, special low-power computing hardware is designed based on the memristor-CMOS hybrid technology.

Convolutional operation is the most frequently used in the deep learning neural network and has the characteristic of kernel translation invariance in operation. Convolution is actually a mathematical matrix multiplication and addition operation. With a convolution kernel as a template, convolution operation is performed with a small piece of data selected from input data. The convolution kernel has the feature of translation invariance. Lateral and vertical translation is carried out on an input data matrix, with one cell at a time (overlapping with the last input data) until the whole input picture is covered, resulting in a large amount of data output. Convolution operation occupies most of the operation of the convolutional neural network, and the energy consumption thereof determines the overall energy consumption.

The translation invariance of the convolution kernel means that weighted data does not need frequent updating. In fact, for a specific convolution kernel, not only one picture needs processing, but also mass pictures need processing. Therefore, the scheme of fusion of storage and computation can greatly reduce the power consumption of convolution computation.

Memristor is a new kind of device with programmable resistance characteristics and is the recent research hotspot. The processing technology of memristors can be compatible with CMOS.

Therefore, how to use memristors to provide a memristor-CMOS hybrid multiplication core circuit reducing overall energy consumption is a problem to be urgently solved by those skilled in the art.

### SUMMARY

In view of this, the present invention provides a memristor-CMOS hybrid multiplication core circuit reducing overall energy consumption, in which one input of multiplication can be stored in a memristor network, one part of operation is completed in a memory network, the other part of operation is completed through a CMOS circuit, thereby reducing frequent data calls by half, and the power consumption of the CMOS circuit is further reduced by reducing competitive adventure in the operation process, thereby greatly reducing the overall energy consumption.

To achieve the above purpose, the present invention provides the following technical solution:

A memristor array, comprises metal wires and memristors; the metal wires are arranged laterally and vertically; a memristor is arranged at the intersection of every two metal wires; the connection/disconnection of the metal wires is judged according to the “relative magnitude” of the resistance values of the memristors; and an adder is constituted according to the resistance value states of the memristors.

Preferably, in the memristor array, the adder comprises: a 7*4 memristor array, wherein five lateral metal wires are taken as inputs, and two metal wires are respectively output sum and output carry; For groups of memristors 1-1 and 2-1, memristors 3-2 and 4-2, memristors 4-3 and 5-3, memristors 6-1 and 6-2 and memristors 7-3 and 7-4, one of each group is in the high resistance state, and the other one is in the low resistance state; a memristor 4-4 is in the low resistance state; and other memristors are in the high resistance state.

Preferably, in the memristor array, the adder comprises a full-adder and a half-adder; an addend and a summand are inputs, and the output sum and the output carry are outputs to constitute the half-adder; and an addend, a summand and low-bit output carry are inputs, and the output sum and the output carry are outputs to constitute the full-adder.

A multiplier, comprises that: the product of a multiplicator and each bit of a multiplicand is taken as an input, the output sum of the half-adder is taken as a low-bit output or the input of a full-adder at the next level, and the output carry is taken as the input of a high-bit full-adder; and the output sum of the full-adder is taken as an output or the input of the full-adder at the next level, and the output carry is taken as the input of the high-bit full-adder.

Preferably, in the multiplier array, the multiplicator and each bit of the multiplicand are taken as inputs, and the product form is obtained through an AND gate circuit.

Preferably, in the multiplier array, the full-adder comprises a CMOS full-adder and a full-adder composed of a memristor array.

It can be know from the above technical solution that compared with the prior art, the present invention discloses a memristor-CMOS hybrid multiplication core circuit, in which one input of multiplication can be stored in a memristor network, one part of operation is completed in a memory network, the other part of operation is completed through a CMOS circuit, thereby reducing frequent data calls by half, and the power consumption of the CMOS circuit is further reduced by reducing competitive adventure in the operation process, thereby greatly reducing the overall energy consumption.

Compared with the prior art, the present invention has the following technical effects:

1. Operation time: compared with the traditional wallace-tree digital multiplier architecture, the present invention reduces the data scheduling time of Y and reduces the data scheduling time by half. Then, for the half-adder and the full-adder of the switching network of the present invention, because the parasitic capacitance of the switching network is extremely small, the operation time can be ignored, and the operation time of the whole adder unit can be reduced by more than 80%, which is equivalent to reducing the critical path delay of the whole multiplier unit by about 13%.

2. Power consumption of operation: the present invention reduces the writing of the CMOS adder (comprising the full-adder and the half-adder) in the wallace-tree multiplier by 5/12. From the prospective of reducing competitive adventure, the operation rate of the adder of the switching network is high, which avoids competitive adventure caused by the adder due to unstable input data in subsequent links, so as to reduce additional power consumed by the factor.

### DESCRIPTION OF DRAWINGS

To more clearly describe the technical solution in the embodiments of the present invention or in the prior art, the drawings required to be used in the description of the embodiments or the prior art will be simply presented below. Apparently, the drawings in the following description are merely the embodiments of the present invention, and for those ordinary skilled in the art, other drawings can also be obtained according to the provided drawings without contributing creative labor.

FIG. 1 is a schematic diagram of a wallace-tree digital multiplier of the present invention;

FIG. 2 is a schematic diagram of a switching network of a half-adder of the present invention;

FIG. 3 is a schematic diagram of a switching network of a full-adder of the present invention;

FIG. 4 is a schematic diagram of a traditional wallace-tree digital multiplier of the present invention.

### DETAILED DESCRIPTION

The technical solution in the embodiments of the present invention will be clearly and fully described below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

Embodiments of the present invention disclose a memristor-CMOS hybrid multiplication core circuit, in which one input of multiplication can be stored in a memristor network, one part of operation is completed in a memory network, the other part of operation is completed through a CMOS circuit, thereby reducing frequent data calls by half, and the power consumption of the

CMOS circuit is further reduced by reducing competitive adventure in the operation process, thereby greatly reducing the overall energy consumption.

A half-adder based on a memristor array, comprises a 7*4 memristor array; the 7*4 memristor array comprises metal wires and memristors; the metal wires are arranged laterally and vertically; a memristor is arranged at the intersection of every two metal wires; the connection/disconnection of the metal wires is judged according to the relative magnitude of the resistance values of the memristors; an adder is constituted according to the resistance value states of the memristors; five lateral metal wires of the 7*4 memristor array are taken as inputs, and two metal wires are respectively output sum and output carry; For groups of memristors 1-1 and 2-1, memristors 3-2 and 4-2, memristors 4-3 and 5-3, memristors 6-1 and 6-2 and memristors 7-3 and 7-4, one of each group is in the high resistance state, and the other one is in the low resistance state; a memristor 4-4 is in the low resistance state; and other memristors are in the high resistance state.

To further optimize the above technical solution, the half-adder has the same structure as the full-adder.

A multiplier containing a half-adder based on a memristor array further comprises a CMOS half-adder and a CMOS full-adder; the half-adder, the CMOS half-adder and the CMOS full-adder constitute a wallace-tree digital multiplier; the product of a multiplicator and each bit of a multiplicand is taken as an input, the output sum of the half-adder is taken as a low-bit output or the input of a full-adder at the next level, and the output carry is taken as the input of a high-bit full-adder; and the output sum of the full-adder is taken as an output or the input of the full-adder at the next level, and the output carry is taken as the input of the high-bit full-adder.

A multiplier containing a half-adder based on a memristor array is characterized by further comprising a CMOS full-adder; the half-adder, the full-adder and the CMOS full-adder constitute a wallace-tree digital multiplier; the product of a multiplicator and each bit of a multiplicand is taken as an input, the output sum of the half-adder is taken as a low-bit output or the input of a full-adder at the next level, and the output carry is taken, as the input of a high-bit full-adder; and the output sum of the full-adder is taken as an output or the input of the full-adder at the next level, and the output carry is taken as the input of the high-bit full-adder.

To further optimize the above technical solution, the multiplicator and each bit of the multiplicand are taken as inputs, and the product form is obtained through an AND gate circuit.

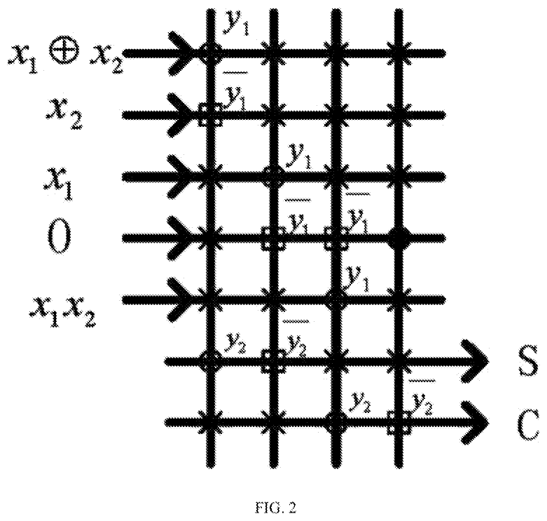

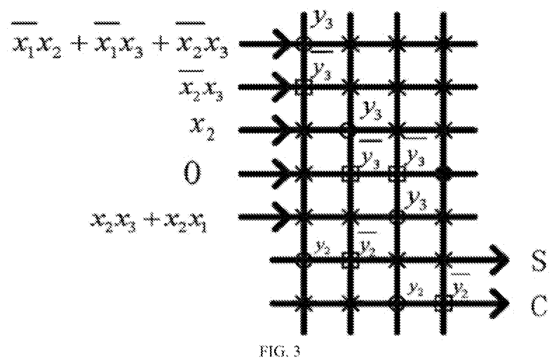

As shown in FIG. 2 and FIG. 3, the resistance values of the memristors are set according to the follow rules to enable the memristor array to complete operation. × indicates that the memristors always keep high resistance, and lateral and vertical metal wires are disconnected;

Black dot indicates that the memristors always keep low resistance, and lateral and vertical metal wires are connected;

Circle and square indicate that the resistance values of the memristors are set to complementary resistance values (high and low) according to the value of yi so that the vertical metal wires are selectively connected with one of lateral metal wires.

As shown in FIG. 2, it is assumed that the inputs of the half-adder are x1y1 and x2y2, the output sum:

Output carry:

As shown in FIG. 3, the output sum:

Output carry:

Embodiment 1

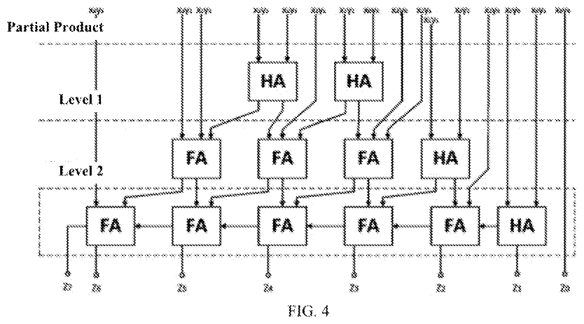

FIG. 4 shows a traditional wallace-tree digital multiplier, multiplication of 4 bits by 4 bits, as an example, is divided into level 1, level 2 and output level, and partial product, as an input, is obtained by a multiplicator and each bit of a multiplicand through an AND gate circuit; X0Y0 is the unit's place Z0; X0Y1 and X1Y0 are taken as inputs of a first CMOS half-adder, the output sum is the ten's place Z1, and the output carry is taken as the input of the CMOS full-adder of the output-level hundred's place; X0Y2 and X1Y1 are taken as inputs of a second CMOS half-adder, the output sum, X2Y0 and the output carry of the first CMOS half-adder are jointly taken as inputs of the CMOS full-adder of the hundred's place, and the output sum is the hundred's place Z2; X1Y2 and X0Y3 are taken as inputs of a third CMOS half-adder; the output sum of the third CMOS half-adder, X3Y0 and X2Y1 are jointly taken as inputs of the CMOS full-adder of the level 2 thousand's place; the output sum of the CMOS full-adder of the level 2 thousand's place, the output carry of the second CMOS half-adder and the output carry of the CMOS full-adder of the output-level hundred's place are taken as inputs of the CMOS full-adder of the output-level thousand's place, and the output sum is the thousand's place Z3; X2Y2 and X1 Y3 are taken as inputs of a fourth CMOS half-adder; the output sum of the fourth CMOS half-adder, X3Y1 and the output carry of the third CMOS half-adder are jointly taken as inputs of the CMOS full-adder of the level 2 ten thousand's place; the output sum of the CMOS full-adder of the level 2 ten thousand's place, the output carry of the second CMOS full-adder of the level 2 thousand's place and the output carry of the CMOS full-adder of the output-level thousand's place are taken as inputs of the CMOS full-adder of the output-level ten thousand's place, and the output sum of the CMOS full-adder of the output-level ten thousand's place is the ten thousand's place Z4; X3Y2, X2Y3 and the output carry of the fourth CMOS half-adder are taken as inputs of the full-adder (dotted portion) of the level 2 hundred thousand's place; the output sum, of the full-adder of the level 2 hundred thousand's place, the output carry of the CMOS full-adder of the level 2 ten thousand's place and the output carry of the CMOS full-adder of the output-level ten thousand's place are taken as inputs of the CMOS full-adder of the output-level hundred thousand's place, and the output sum is the hundred thousand's place Z5; X3Y3, the output carry of the full-adder of the level 2 hundred thousand's place and the output carry of the CMOS full-adder of the output-level hundred thousand's place are taken as inputs of the CMOS full-adder of the output-level million's place; and the output sum of the CMOS full-adder of the output-level, million's place is the million's place Z6, and the output carry is the ten million's place Z7.

Embodiment 2

On the basis of embodiment 1, one or more of a first CMOS half-adder, a second CMOS half-adder, a third CMOS half-adder and a fourth CMOS half-adder are transformed into a half-adder composed of a memristor array.

Embodiment 3

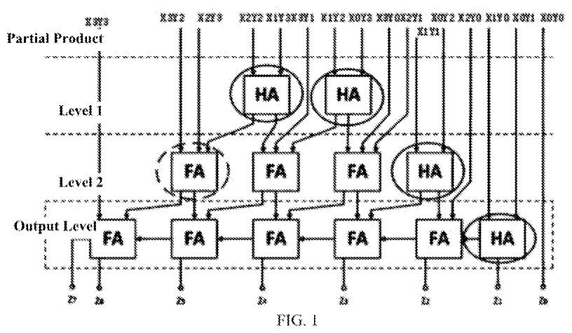

As shown in FIG. 1, multiplication of 4 bits by 4 bits, as an example, is divided into level 1, level 2 and output level, and partial product, as an input, is obtained by a multiplicator and each bit of a multiplicand through an AND gate circuit; X0Y0 is the unit's place Z0; X0Y1 and X1Y0 are taken as inputs of a first half-adder, the output sum is the ten's place Z1, and the output carry is taken as the input of the CMOS full-adder of the output-level hundred's place; X0Y2 and X1Y1 are taken as inputs of a second half-adder, the output sum, X2Y0 and the output carry of the first half-adder are jointly taken as inputs of the CMOS full-adder of the hundred's place, and the output sum is the hundred's place Z2; X1Y2 and X0Y3 are taken as inputs of a third half-adder; the output sum of the third half-adder, X3Y0 and X2Y1 are jointly taken as inputs of the CMOS full-adder of the level 2 thousand's place; the output sum of the CMOS full-adder of the level 2 thousand's place, the output carry of the second half-adder and the output carry of the CMOS full-adder of the output-level hundred's place are taken as inputs of the CMOS full-adder of the output-level thousand's place, and the output sum is the thousand's place Z3; X2Y2 and X1Y3 are taken as inputs of a fourth half-adder; the output sum of the fourth half-adder, X3 Y1 and the output carry of the third half-adder are jointly taken as inputs of the CMOS full-adder of the level 2 ten thousand's place; the output sum of the CMOS full-adder of the level 2 ten thousand's place, the output carry of the second CMOS full-adder of the level 2 thousand's place and the output carry of the CMOS full-adder of the output-level thousand's place are taken as inputs of the CMOS full-adder of the output-level ten thousand's place, and the output sum of the CMOS full-adder of the output-level ten thousands place is the ten thousand's place Z4; X3Y2, X2Y3 and the output carry of the fourth half-adder are taken as inputs of the first full-adder (dotted portion); the output sum of the first full-adder, the output carry of the CMOS full-adder of the level 2 ten thousand's place and the output carry of the CMOS full-adder of the output-level ten thousand's place are taken as inputs of the CMOS full-adder of the output-level hundred thousand's place, and the output sum is the hundred thousand's place Z5; X3Y3, the output carry of the first full-adder and the output carry of the CMOS full-adder of the output-level hundred thousand's place are taken as inputs of the CMOS full-adder of the output-level million's place; and the output sum of the CMOS full-adder of the output-level million's place is the million's place Z6, and the output carry is the ten million's place Z7.

Each embodiment in the description is described in a progressive way. The difference of each embodiment from each other is the focus of explanation. The same and similar parts among all of the embodiments can be referred to each other. For a device disclosed by the embodiments, because the device corresponds to a method disclosed by the embodiments, the device is simply described. Refer to the description of the method part for the related part.

The above description of the disclosed embodiments enables those skilled in the art to realize or use the present invention. Many modifications to these embodiments will be apparent to those skilled in the art. The general principle defined herein can be realized in other embodiments without departing from the spirit or scope of the present invention. Therefore, the present invention will not be limited to these embodiments shown herein, but will conform to the widest scope consistent with the principle and novel features disclosed herein.

1. A half-adder based on a memristor array, wherein the half-adder comprises a 7*4 memristor array; the 7*4 memristor array comprises metal wires and memristors; the metal wires are arranged laterally and vertically; a memristor is arranged at the intersection of every two metal wires; the connection disconnection of the metal wires is judged according to the relative magnitude of the resistance values of the memristors ; an adder is constituted according to the resistance value states of the memristors; five lateral metal wires of the 7*4 memristor array are taken as inputs, and two metal wires are respectively output sum and output carry; For groups of memristors 1-1 and 2-1, memristors 3-2 and 4-2, memristors 4-3 and 5-3, memristors 6-1 and 6-2 and memristors 7-3 and 7-4, one of each group is in the high resistance state, and the other one is, in the low resistance state; a memristor 4-4 is in the low resistance state; and other memristors are in the high resistance state.

2. The half-adder based on a memristor array according to claim 1, wherein the half-adder has the same structure as a full-adder.

3. A multiplier containing the half-adder based on a memristor array of claim 1, further comprising a CMOS half-adder and a CMOS full-adder; the half-adder, the CMOS half-adder and the CMOS full-adder constitute a wallace-tree digital multiplier; the product of a multiplicator and each bit of a multiplicand is taken as an input, the output sum of the half-adder is taken as a low-bit output or the input of a full-adder at the next level, and the output carry is taken as the input of a high-bit full-adder; and the output sum of the full-adder is taken as an output or the input of the full-adder at the next level, and the output carry is taken as the input of the high-bit full-adder.

4. A multiplier containing the half-adder based on a memristor array of claim 2, further comprising a CMOS full-adder; the half-adder, the full-adder and the CMOS full-adder constitute a wallace-tree digital multiplier; the product of a multiplicator and each bit of a multiplicand is taken as an input, the output sum of the half-adder is taken as a low-bit output or the input of a full-adder at the next level, and the output carry is taken as the input of a high-bit full-adder; and the output sum of the full-adder is taken as an output or the input of the full-adder at the next level, and the output carry is taken as the input of the high-bit full-adder.

5. The multiplier according to claim 3, wherein the multiplicator and each bit of the multiplicand are taken as inputs, and the product form is obtained through an AND gate circuit.

6. The multiplier according to claim 4, wherein the multiplicator and each bit of the multiplicand are taken as inputs, and the product form is obtained through an AND gate circuit.
